(19) United States
(12) Patent Application Publication
(10) Pub. No.: US 2008/0318139 A1
(43) Pub. Date: Dec. 25, 2008

(54) Mask Blank, Photomask and Method of Manufacturing a Photomask

(75) Inventors: Uwe Dersch, Dresden (DE); Haiko Rolff, Dresden (DE); Pavel Nesladek, Dresden (DE)

Correspondence Address: MAYBACK & HOFFMAN, P.A., 5722 S. FLAMINGO ROAD #232, FORT LAUDERDALE, FL, 33330, US

(73) Assignee: ADVANCED MASK TECHNOLOGY CENTER GMBH & CO. KG, Dresden (DE)

(21) Appl. No.: 12/144,330

(22) Filed: Jun. 23, 2008

(30) Foreign Application Priority Data
Jun. 22, 2007 (DE) 10 2007 028 800.1

(51) Int. Cl. G03F 1/00

(52) U.S. Cl. 430/5

(57) ABSTRACT

Mask blanks of the invention include an absorber layer, an anti-reflective layer disposed over the absorber layer, and a hard mask layer disposed over the anti-reflective layer. The absorber layer is absorbent at an exposure wavelength and is reflective at an inspection wavelength. The inspection wavelength is greater than or equal to the exposure wavelength. The anti-reflective layer is not reflective at the inspection wavelength. None of the main constituents of the hard mask layer has an atomic number greater than 41. The mask blank may be a reflective EUVL mask blank or a transparent mask blank.

### CROSS-REFERENCE TO RELATED APPLICATIONS

This application claims the priority, under 35 U.S.C. § 119, of copending German Application No. 10 2007 028 800.1, filed Jun. 22, 2007, which designated the United States and was not published in English; the prior application is herewith incorporated by reference herein in its entirety.

### BACKGROUND OF THE INVENTION

Embodiments of the invention relate to photomasks used, for example, for fabricating semiconductor integrated circuits and to methods of manufacturing a photomask. For mask technologies like extreme ultraviolet lithography (EUVL), as well as improved optical lithography platforms, for example, double patterning or hyper NA immersion lithography, an absorber layer is patterned through a resist mask. The resolution that may be achieved depends mainly on the required resist thickness as well as on the type of resist. A thin resist layer is needed to achieve a high resolution. On the other hand, the resist pattern is consumed during the pattern transfer from the resist layer into the absorber layer such that the resist must be sufficiently thick.

With regard to EUV lithography, the absorber pattern usually reflects radiation that is used during an optical inspection of the absorber pattern. Therefore, the absorber layer is usually coated with an anti-reflective layer, the reflectivity of which, at the inspection wavelength, is lower than that of the absorber layer. The anti-reflective layer enhances the contrast during a subsequent mask inspection. In general, anti-reflective layers are resistant versus typical etch processes transferring a resist pattern into the absorber layer.

In addition, transparent photomasks as usually used for DUV and UV lithography use chromium containing layers to form opaque areas on the mask. Patterning of chromium containing layers requires typically oxygen-based etch processes to form a volatile chromium compound, for example, CrO₂Cl₂. Oxygen-based etch processes, however, show usually an isotropic component influencing the pattern size (line width) in the mask pattern.

U.S. Pat. No. 6,720,118 B2 to Yan et al. discloses an EUV mask absorber stack that comprises an absorber layer based on a metal nitride, for example, titanium or tantalum nitride, and an anti-reflective layer covering the absorber layer and containing another tantalum or titanium compound containing one or more non-metals like fluorine (F), oxygen (O), argon (Ar), carbon (C), hydrogen (H), nitrogen (N), germanium (Ge) and boron (B).

A need exists for photomasks with high efficient absorber layers that have a short absorption length at the exposure wavelength and that may be patterned with high resolution and further for a method of patterning photomasks comprising such a high efficient absorber layer and an anti-reflective layer.

### BRIEF SUMMARY OF THE INVENTION

With the foregoing and other objects in view, there is provided, in accordance with the invention, a mask blank, including an absorber layer being absorbent at an exposure wavelength and being reflective at an inspection wavelength, the inspection wavelength being greater than the exposure wavelength, an anti-reflective layer disposed over the absorber layer and being low-reflective at the inspection wavelength, and a hard mask layer disposed over the anti-reflective layer, the hard mask layer having constituents with an atomic number less than or equal to 41.

A mask blank according to an embodiment of the invention comprises an absorber layer that is absorbent at an exposure wavelength and that is reflective at an inspection wavelength, wherein the exposure wavelength is used in a lithography process to transfer patterns from a photomask into, for example, a semiconductor wafer. The exposure wavelength may be, for example, 13.5 nm. The inspection wavelength is that of a typical optical defect detection tool and is greater than the exposure wavelength, for example, 193 nm, 196 nm or 248 nm.

An anti-reflective layer is disposed over the absorber layer, the anti-reflective layer being low-reflective at the inspection wavelength. The anti-reflective layer may be disposed directly on the absorber layer. Further, a hard mask layer is disposed over the anti-reflective layer. The hard mask layer may be disposed directly on the anti-reflective layer to have the hard mask layer be in contact with the anti-reflective layer. In accordance with other embodiments, a further layer may be disposed between the hard mask layer and the anti-reflective layer. None of the constituents of the hard mask layer has an effective atomic number greater than 41. By selecting a suitable material for the hard mask layer and a suitable etch process, a first etch selectivity S1=R(HM)/R(Res) between the material of the hard mask layer having an etch rate R(HM) and a resist disposed above the hard mask layer for patterning the hard mask and having an etch rate R(Res) is greater than a second etch selectivity S2, with S2=R(AR)/R(Res) between the material of the anti-reflective layer having an etch rate R(AR) and the resist.

Thus, a resist layer used for patterning the mask blank may be thinner than without hard mask. Further, due to the low atomic number of the constituents of the hard mask layer, electron back scattering during electron beam writing of the resist layer disposed over the hard mask layer is reduced.

In accordance with another feature of the invention, a resist layer may cover the hard mask layer. The hard mask layer may have an etch rate in a fluorine- or chlorine-based etch process that is not smaller than that of the anti-reflective layer to facilitate the application of thin resist layers that are thinner than, for example, 160 nm.

In accordance with a further feature of the invention, the hard mask layer may be soluble in a HF solution to avoid, during removal of hard mask residuals, damaging of the absorber layer, the anti-reflective layer, or the underlayer.

In accordance with an added feature of the invention, each main constituent of the hard mask layer may have an atomic number of 24 or less, for example, 6, to reduce electron back scattering effects during electron beam exposure or exposure with any charged particles. The term main constituent or constituent here and in the following does not include contaminations due to process imperfectness.

In accordance with an additional feature of the invention, the hard mask layer may contain silicon and oxygen, for example, the hard mask layer may be a silicon dioxide layer or a silicon oxynitride layer that show high etch resistance in fluorine-based etch processes. According to another embodiment, the hard mask layer may comprise or consist of chromium or carbon. The mask blank may be that of an EUVL mask with a capped or non-capped multi-layer reflector disposed below the absorber layer or a transparent mask with a carrier substrate supporting the absorber layer, the carrier substrate being transparent at an exposure wavelength of at least 193 nm. In an embodiment, the inspection wavelength can go up to but not exceed 800 nm.

In accordance with yet another feature of the invention, the absorber layer comprises a transition metal nitride, the transition metal forming one of a volatile fluorine compound and a volatile chlorine compound.

With the objects of the invention in view, there is also provided a photomask including a carrier substrate that is transparent at an exposure wavelength and an absorber layer that is opaque at the exposure wavelength and that is reflective at an inspection wavelength, the inspection wavelength being greater than the exposure wavelength. An anti-reflective layer disposed over the absorber layer is less reflective than the absorber layer at the inspection wavelength. As the anti-reflective layer shows lower reflectivity at the inspection wavelength than, for example, a chromium-based layer, a photomask according to this embodiment shows increased contrast during defect detection.

In accordance with yet a further feature of the invention, a hard mask layer may be disposed over the anti-reflective layer, none of the constituents of the hard mask layer having an atomic number greater than 41. The same hard mask layer configuration may be also used for EUVL masks. As a consequence, transparent masks and the reflective mask may be patterned using the same or substantially the same etch chemistry.

In accordance with yet an added feature of the invention, there is provided a carrier substrate disposed below the absorber layer and transparent at an exposure wavelength that is at least 100 nanometers.

In accordance with yet an additional feature of the invention, a resist layer may cover the hard mask layer and/or a phase shift layer may be disposed between the carrier substrate and the absorber layer.

In accordance with again another feature of the invention, the anti-reflective layer and the absorber layer are patterned to form an absorber pattern comprising absorber structures, wherein between the absorber structures sections of an underlayer, for example, the carrier substrate, are exposed.

With the objects of the invention in view, there is also provided a method of manufacturing a photomask, wherein a mask blank is provided that includes an anti-reflective layer disposed over an absorber layer and a hard mask layer disposed over, for example, directly on the anti-reflective layer. The hard mask layer is patterned to form a hard mask and the pattern of the hard mask is transferred into the anti-reflective layer. Then, the pattern of the anti-reflective layer is transferred into the absorber layer so that sections of an underlayer, for example, a carrier substrate, are exposed. The hard mask layer may be patterned by transferring a resist mask pattern into the hard mask layer. The resist mask may be thin, for example, about 100 nm or less so that the resist may be patterned at a high resolution. Residuals of the resist mask may be stripped before the pattern of the anti-reflective layer is transferred into the absorber layer so that the stripping of resist residuals may not damage an underlayer beneath the absorber layer.

In accordance with again a further mode of the invention, the hard mask residuals may be stripped through a wet-etch process after the anti-reflective layer is patterned.

In accordance with a concomitant mode of the invention, the hard mask layer patterning step is carried out by transferring a resist mask pattern into the hard mask layer and residuals of the resist mask pattern are stripped before transferring the pattern of the anti-reflective layer into the absorber layer.

Although the invention is illustrated and described herein as embodied in a mask blank, a photomask, and a method for manufacturing a photomask, it is, nevertheless, not intended to be limited to the details shown because various modifications and structural changes may be made therein without departing from the spirit of the invention and within the scope and range of equivalents of the claims. Additionally, well-known elements of exemplary embodiments of the invention will not be described in detail or will be omitted so as not to obscure the relevant details of the invention.

Other features that are considered as characteristic for the invention are set forth in the appended claims. As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one of ordinary skill in the art to variously employ the present invention in virtually any appropriately detailed structure. Further, the terms and phrases used herein are not intended to be limiting; but rather, to provide an understandable description of the invention. While the specification concludes with claims defining the features of the invention that are regarded as novel, it is believed that the invention will be better understood from a consideration of the following description in conjunction with the drawing figures, in which like reference numerals are carried forward. The figures of the drawings are not drawn to scale.

Before the present invention is disclosed and described, it is to be understood that the terminology used herein is for the purpose of describing particular embodiments only and is not intended to be limiting. The terms “a” or “an”, as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The term “coupled,” as used herein, is defined as connected, although not necessarily directly, and not necessarily mechanically.

As used herein, the term “about” or “approximately” applies to all numeric values, whether or not explicitly indicated. These terms generally refer to a range of numbers that one of skill in the art would consider equivalent to the recited values (i.e., having the same function or result). In many instances these terms may include numbers that are rounded to the nearest significant figure.

### BRIEF DESCRIPTION OF THE DRAWINGS

Features and advantages of embodiments of the invention will be apparent from the following description of the drawings. The drawings are not necessarily to scale. Emphasis is placed upon illustrating the principles.

FIG. 1A is a diagrammatic, fragmentary, cross-sectional view of a section of an EUV mask blank comprising a hard mask layer according to an embodiment of the invention;

FIG. 1B is a diagrammatic, fragmentary, cross-sectional view of a section of an EUV mask blank comprising a hard mask layer and a resist layer according to a further embodiment of the invention.

FIG. 1C is a diagrammatic, fragmentary, cross-sectional view of a section of an EUV mask comprising an absorber pattern resulting from a method of manufacturing a lithographic mask according to a further embodiment of the invention.

FIG. 2A is a diagrammatic, fragmentary, cross-sectional view of a section of a transparent photomask blank comprising an absorber stack and a hard mask layer according to another embodiment of the invention.

FIG. 2B is a diagrammatic, fragmentary, cross-sectional view of a section of a transparent photomask blank comprising a hard mask layer and a resist layer according to a further embodiment of the invention.

FIG. 2C is a diagrammatic, fragmentary, cross-sectional view of a section of a transparent photomask comprising an absorber pattern resulting from a method of manufacturing a lithographic mask according to a further embodiment of the invention.

FIG. 3A is a diagrammatic, fragmentary, cross-sectional view of a section of a transparent phase-shift mask blank comprising an absorber stack and a hard mask layer according to another embodiment of the invention.

FIG. 3B is a diagrammatic, fragmentary, cross-sectional view of a section of a transparent phase-shift mask blank comprising a hard mask layer and a resist layer according to a further embodiment of the invention.

FIG. 3C is a diagrammatic, fragmentary, cross-sectional view of a section of a transparent phase-shift mask comprising an absorber pattern which results from a method of manufacturing a lithographic mask according to a further embodiment of the invention.

FIG. 4A is a diagrammatic, fragmentary, cross-sectional view of a section of an EUV mask comprising an absorber stack, a hard mask layer, and a resist layer illustrating a method of manufacturing a lithographic mask according to another embodiment of the invention, after patterning the resist layer.

FIG. 4B is a diagrammatic, fragmentary, cross-sectional view of the EUV mask section of FIG. 4A after patterning the hard mask layer.

FIG. 4C is a diagrammatic, fragmentary, cross-sectional view of the EUV mask section of FIG. 4A after patterning a top layer of the absorber stack.

FIG. 4D is a diagrammatic, fragmentary, cross-sectional view of the EUV mask section of FIG. 4A after stripping resist layer residuals.

FIG. 4E is a diagrammatic, fragmentary, cross-sectional view of the EUV mask section of FIG. 4A after patterning an absorber layer of the absorber stack.

FIG. 4F is a diagrammatic, fragmentary, cross-sectional view of the EUV mask section of FIG. 4A after removing hard mask layer residuals.

FIG. 5 is a flow chart illustrating a method of manufacturing a lithographic mask according to a further embodiment of the invention.

### DETAILED DESCRIPTION OF THE INVENTION

Herein various embodiment of the present invention are described. In many of the different embodiments, features are similar. Therefore, to avoid redundancy, repetitive description of these similar features may not be made in some circumstances. It shall be understood, however, that description of a first-appearing feature applies to the later described similar feature and each respective description, therefore, is to be incorporated therein without such repetition.

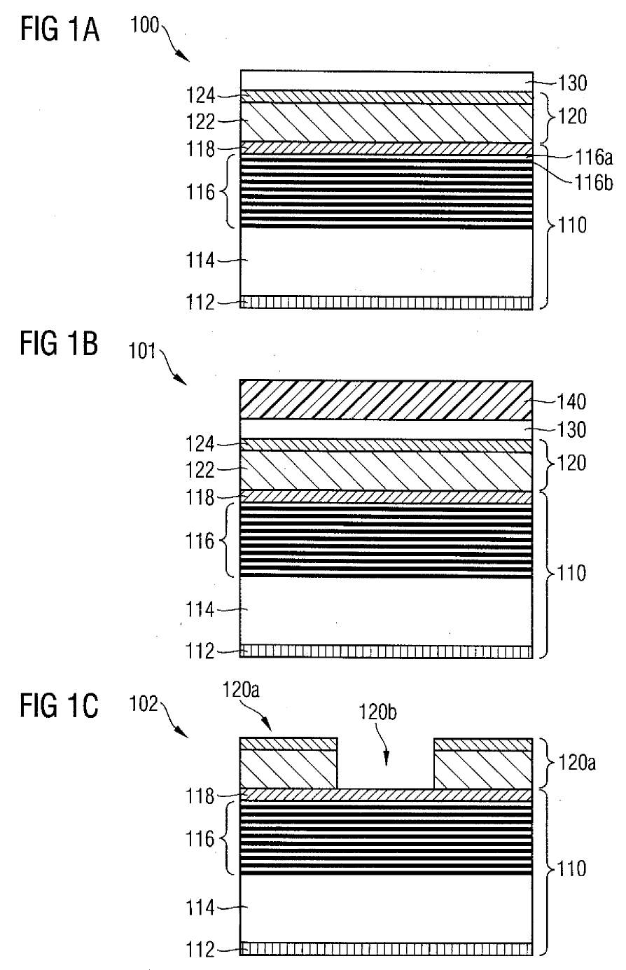

In the figures of the drawings, unless stated otherwise, identical reference symbols denote identical parts. FIGS. 1A to 1C refer to reflective photomasks, for example to EUV lithography masks.

Referring now to the figures of the drawings in detail and first, particularly to FIG. 1A thereof, there is shown a cross-sectional view of an EUV mask blank 100 comprising a base section 110, an absorber stack 120, and a hard mask layer 130. The base section 110 may comprise a carrier substrate 114. The carrier substrate 114 may be a glass, ceramic, or another silicon oxide material with a low thermal extension coefficient, for example, silicon dioxide doped with titanium dioxide. The base section 110 may further comprise a multilayer reflector 116. The multilayer reflector 116 may comprise 20 to 100 bi-layers, wherein each bi-layer comprises a first layer 116a of a first material having a high atomic number and a second layer 116b of another material having a low atomic number. The bi-layers are disposed such that the first and the second layers 16a, 116b are in alternating order. The first layer 116a acts as a scattering layer. The second layer 116b acts as a spacing layer having minimal absorption at the exposure radiation wavelength. For example, the first layer 116a may be a molybdenum layer having an effective atomic number of about 42 and the second layer 116b may be a silicon layer having an effective atomic number of about 14. At an exposure wavelength of, for example 13.5 nm, each bi-layer may comprise a 1.5 to 3.5 nm thick molybdenum layer and a 3.0 to 5.0 nm thick silicon layer. Further, a backside layer 112 may face the multilayer reflector 1116 at the carrier substrate 114. The backside layer 112 may be conductive to facilitate electrostatic chucking. The backside layer 112 may be, for example, a chromium layer, which may be about 70 nm thick. The base section 110 may further comprise a capping layer 118, which may be, for example, a layer comprising of or containing ruthenium and being about 2.0 to about 4.0 nm thick.

The base section 110 supports the absorber stack 120. The absorber stack 120 may be in contact with the capping layer 118. According to another embodiment, a buffer layer may be disposed between the absorber stack 120 and the base section 110. The absorber stack 120 comprises an absorber layer 122 and an anti-reflective layer 124. The absorber layer 120 may be based on a metal nitride, for example, a transition metal nitride like tantalum or titanium nitride and may have a thickness of about 10 nm to about 90 nm. The absorber layer 122 is absorbent at a first wavelength that corresponds to the exposure wavelength, where the absorbance at the exposure wavelength may be greater than 50%. The absorber layer 122 is typically reflective at a second wavelength, at which the photomask is inspected after patterning. Typically, the reflectance is greater than 40% at typical inspection wavelengths of, for example, 193 nm, 198 nm, 248 nm, 257 nm, 266 nm, 365 nm, or 488 nm. Even greater inspection wavelengths are possible, wherein shorter wavelengths stand for better resolution. Further, mask alignment tools are based on optical pattern detection operating in the visible light wavelength regime.

The absorber stack 120 comprises further an anti-reflective layer 124. The anti-reflective layer 124 is disposed over the absorber layer 122 and is less reflective at the inspection wavelength than the absorber layer 122. The reflectance is typically less than 12% at the respective inspection wavelength. The anti-reflective layer 124 may be based on a metal nitride, for example, a transition metal nitride such as titanium or tantalum nitride, and may further comprise one or more further components selected from a group comprising chlorine, fluorine, argon, hydrogen, or oxygen. The anti-reflective layer 124 may be formed by treating the absorber layer 122 in an ambient containing the further component or precursors of them. According to another embodiment, the anti-reflective layer may be a silicon nitride (Si₃N₄) layer.

The EUV mask blank 100 further comprises a hard mask layer 130, the heaviest constituent having an atomic number of less than 42. The hard mask layer 130 is disposed over the anti-reflective layer 124 and may be in contact with the same. The hard mask layer 130 may have an etch rate of less than 1 nm per second in a fluorine-based dry etch process. For example the atomic number of the heaviest constituent may be less than 25, for example, 24 or 14. According to another embodiment, the atomic number of the heaviest constituent may be less than 14. The thickness of the hard mask layer 130 may be, for example, about 10 to about 30 nm. The hard mask layer 130 may be a silicon oxide layer, for example, a silicon dioxide layer, a silicon oxynitride layer, a carbon layer, or a germanium- and/or aluminum- or chromium-based layer.

The hard mask layer 130 may be patterned using a thin resist layer 130. The thickness of the resist layer 130 may be less than 200 nm, for example about 100 nm, and less than the typical resist thickness required for patterning a typical absorber stack without a hard mask. The thin resist layer facilitates a high-resolution pattern process of the resist layer. Using a fluorine-based dry etch process, a hard mask layer 130 with a thickness of less than 30 nm may be sufficient for breaking through even for high etch-resistant anti-reflective layers 124. The low atomic numbers of the constituents of the hard mask layer 130 reduce electron back scattering during patterning of the resist layer through electron beam writing. The hard mask layer 130 may further protect the anti-reflective layer 124 during a following etch of the absorber layer 122. A degradation of the reflectance of the anti-reflective layer 124, which may deteriorate its reflectance performance during inspection and/or optical pattern recognition, may be avoided. Steep sidewall angles and minimal corner rounding may be achieved. Different anti-reflective layers of different photomask types may be etched using the same hard mask.

FIG. 1B shows a further mask blank 101 comprising a base section 110, an absorber stack 120 and a hard mask layer 130. In addition, the mask blank 101 comprises a resist layer 140. The resist layer 140 may be, for example, an electron resist layer with a thickness of about 60 to about 200 nm. The resist material may be a chemically amplified resist, a self-assembling resist material or a non-chemically amplified resist.

FIG. 1C shows a patterned EUV mask 102 that may result from a mask blank as described with reference to FIGS. 1A or 1B. The EUV mask 102 comprises a non-patterned base section 110 and a patterned absorber stack with absorber structures 120a, which are separated by trenches 120b exposing the base section 110, for example, the capping layer 118, between the absorber structures 120a. As the absorber structures 120a remain coated by remnant portions of the hard mask layer 130 during the complete etch of the trenches 120b, no corner rounding occurs. The steps of the absorber structures are steep. The feature size may be less than 30 nm.

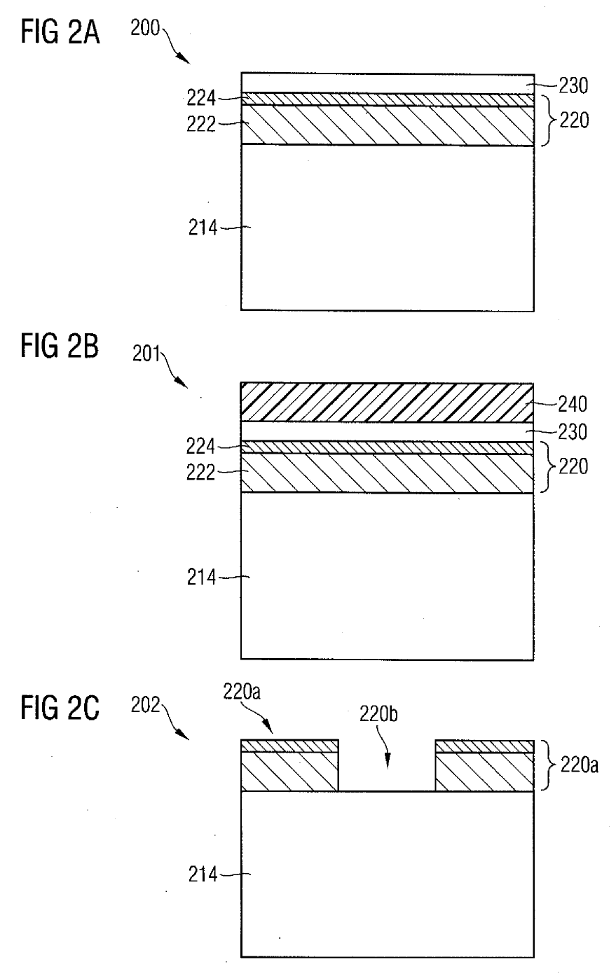

FIGS. 2A to 2C refer to a transparent photomask for use, for example, in DUV or UV lithography

The mask blank 200 as illustrated in FIG. 2A comprises a transparent carrier substrate 214, which may be a glass or a ceramic, for example, a doped silicon dioxide. The mask blank 200 comprises further an absorber stack 220 that includes an absorber layer 222, which is disposed over the carrier substrate 214. The absorber layer 222 may be in contact with the carrier substrate 214 and may be a tantalum nitride layer with a thickness of about 10 to about 100 nm. An anti-reflective layer 224 may cover the absorber layer 222. The anti-reflective layer 224 may be a further tantalum nitride layer containing further components, as, for example, oxygen, fluorine, hydrogen, or argon and may have a thickness of 10 to 14 nm.

A hard mask layer 230 with a thickness of 10 to 30 nm is disposed over the absorber stack 220. The absorber/hard mask layer configuration 220/230 may be the same as for the EUVL mask of FIGS. 1A to 1C. A unique deposition/patterning regime, which is independent of the photomask type, may be implemented. As the etch regime does not require oxygen-based etch chemistry, the pattern etch is highly anisotropic and avoids line shrinking.

FIG. 2B shows a further transparent mask blank 201, which comprises a carrier substrate 214, an absorber stack 220 and a hard mask layer 230 as described with reference to FIG. 2A. In addition, the mask blank 201 comprises a resist layer 240 with a thickness in the range of 50 to 160 nm, for example, 130 nm.

FIG. 2C refers to a patterned transparent mask 202, which may result from one of the mask blanks 200, 201. The patterned transparent photomask 202 comprises a carrier substrate 214 supporting opaque structures 220a that are separated by trenches 220b that expose the carrier substrate 214. At typical inspection wavelengths, the reflectivity of an anti-reflective layer comprising, for example, a tantalum nitride or silicon nitride may be less than 10%, whereas the reflectance of chromium as used for opaque sections in usual transparent masks is about 20%. As a consequence, the contrast during optical inspection and optical pattern recognition may be improved.

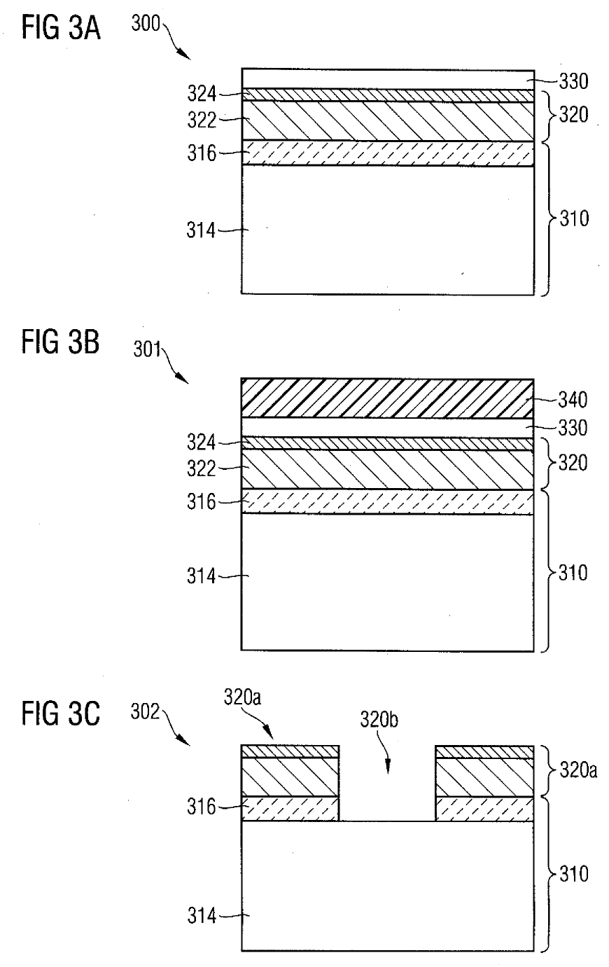

FIGS. 3A to 3C refer to transparent half-tone phase-shift masks 300 to 302. The mask blank 300 as shown in FIG. 3A comprises a base section 310 that includes, in addition to a carrier substrate 314, a phase-shifting layer 316. The carrier substrate 314 may be a glass, for example, a doped silicon dioxide. The phase shifting layer 316 may be a molybdenum silicide with a thickness of about 10 to about 50 nm. The absorber/hard mask layer configuration 320/330 may be the same as that of the mask blanks 100 or 200 as described with reference to FIG. 1A and FIG. 2A.

FIG. 3B refers to a further mask blank 301 that comprises in addition a resist layer 340, which may have a thickness of about 50 to 160 nm, for example, 130 nm.

FIG. 3C shows a patterned phase shift mask 302 with absorber structures 320a that are separated by trenches 320b exposing the carrier substrate 314. According to other embodiments, the phase shift layer 316 is not etched through such that thinned layer sections cover the carrier substrate 314 at the bottom of the trenches 320b.

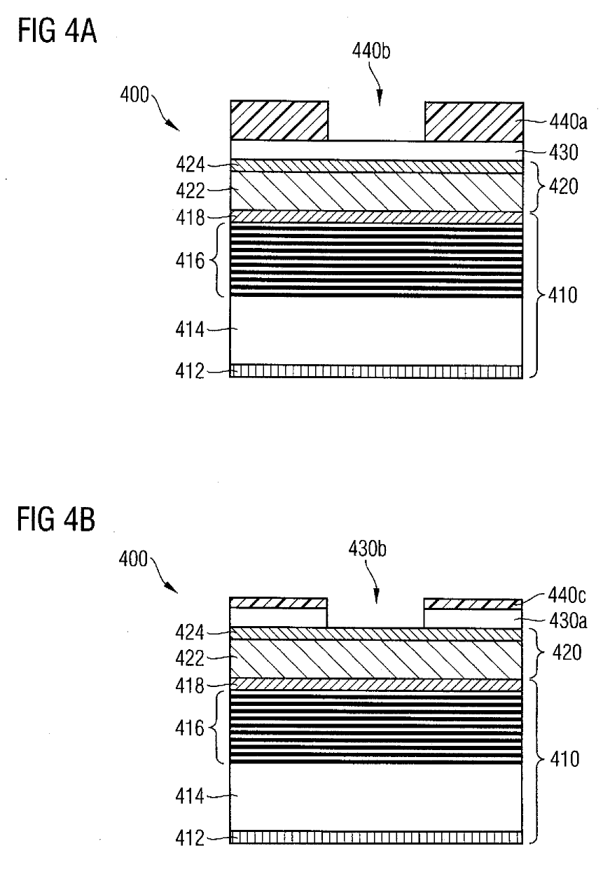

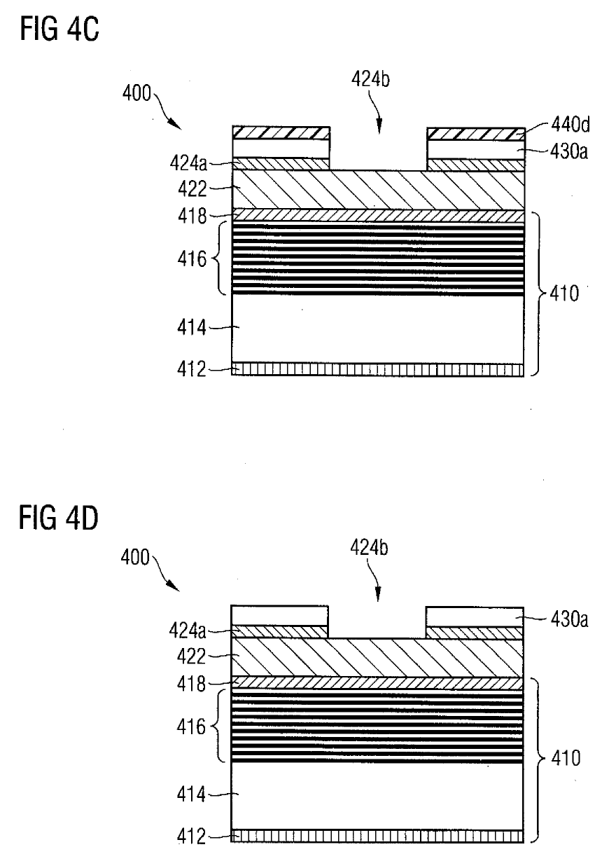

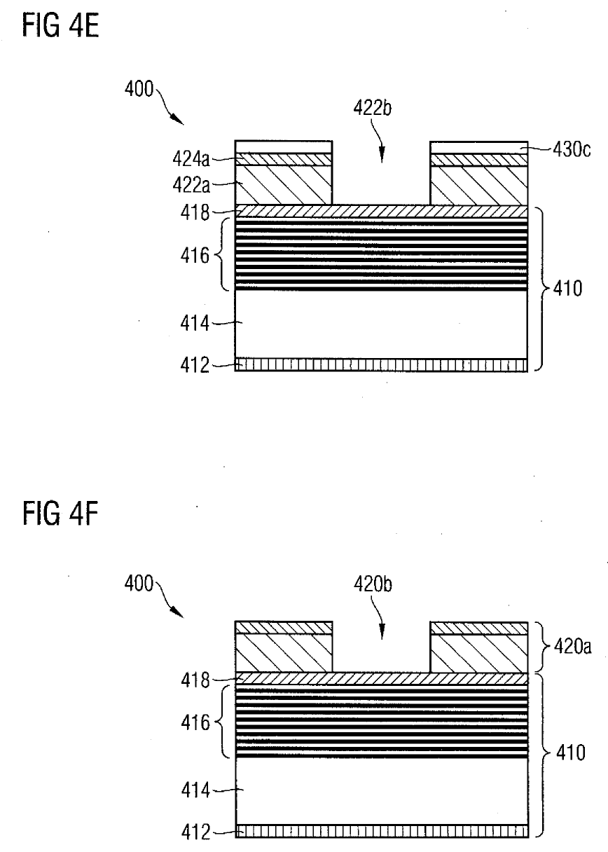

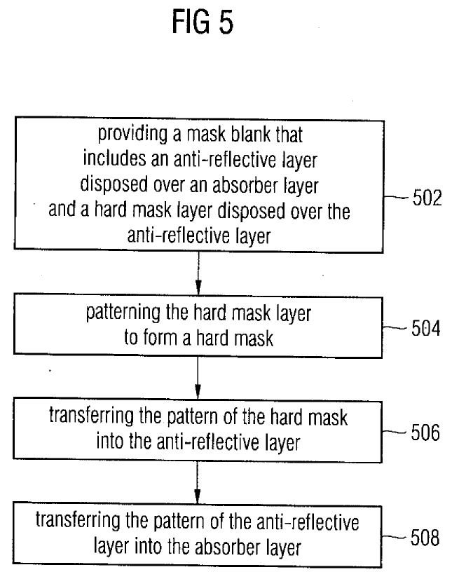

FIGS. 4A to 4F refer to a method of patterning a mask blank as described in FIG. 1A, FIG. 1B, FIG. 2A, FIG. 2B, FIG. 3A or FIG. 3B. Though the cross-sectional views refer to a reflective EUVL mask, the same method may apply to transparent binary and phase shift masks as well.

With regard to FIG. 4A, a mask blank may be provided that comprises an absorber stack 420 supported by a base section 410 and a hard mask layer 430 covering the absorber stack 420, the hard mask layer 430 facing the base section 410 at the absorber stack 420. The absorber stack 420 comprises an absorber layer 422. The absorber layer 422 is highly absorbent at a first wavelength that is equivalent to an exposure wavelength of an exposure radiation to which the photomask will be subjected in a photolithography process utilizing the photomask in a semiconductor wafer patterning process. The exposure wavelength may be, for example, 13.5 nm. The absorbance of the absorber layer 422 at the exposure radiation may be greater than 50%. The absorber layer 422 may contain a transition metal nitride, the transition metal being selected to form a volatile fluorine compound, for example, tantalum nitride. The absorber layer 422 may be reflective at a second wavelength, the second wavelength being equivalent to an inspection wavelength used in an optical inspection method scanning the mask patterns for defects. The inspection wavelength may be, for example, 193 nm, 198 nm, 248 nm, 257 nm, 266 nm, 365 nm, or 488 nm or more. The reflectance of the absorber layer at the inspection wavelength may be greater than 40%. The absorber layer 422 may be in contact with the base section 410. The absorber stack 420 may further comprise an anti-reflective layer 424 covering the absorber layer 422. The anti-reflective layer 424 is low reflective at the inspection wavelength and may show a high etch resistivity against typical etch chemistries used for patterning resist layers. The reflectivity of the anti-reflective layer 424 may be, for example, less than 12%.

The hard mask layer 430 is disposed over the anti-reflective layer 424, for example, directly on the anti-reflective layer 424, and may have an etch rate of less than 1 nm per second in a fluorine-based etch process. The atomic number of the heaviest constituent of the hard mask layer 430 is less than that of molybdenum, for example, 24, or less, for example 6. The hard mask layer 430 may contain or consist of, for example, silicon oxide, silicon oxynitride, a germanium compound, carbon, or chromium. For example, a 10 nm thick chromium hard mask may be sufficiently etch resistive to pattern a TaN-based absorber stack, which is about 40 nm to about 90 nm thick. In accordance with another embodiment, another layer may be provided between the hard mask layer 430 and the anti-reflective layer 424.

The mask blank 400 further includes a resist layer comprising, for example, a chemically amplified electron beam resist, which is about 60 to about 200 nm thick, for example, 130 nm. If the mask blank 400 is supplied without resist layer, at first a resist layer may be deposited upon the hard mask layer 430. The resist layer may be patterned using an electron beam writer or another tool using any kind of charged particles. Due to the low atomic number of the constituents of the hard mask layer 430, electron scattering is reduced compared to a molybdenum or tantalum containing underlayer. As reflected electrons may expose sections of the electron beam resist outside the write track, a fogging effect resulting from the backscattering electrons may be reduced.

FIG. 4A shows the mask blank 400 after patterning the electron beam resist layer. Resist structures 440a, for example, lines and dots, are separated by trenches 440b exposing sections of the hard mask layer 430.

Referring to FIG. 4B, the resist pattern is transferred into the hard mask layer to form a hard mask comprising line- or dot-shaped structures 430a separated by trenches 430b that expose sections of the absorber stack 420. A wet-etch process, which may use, for example, HF, may be carried out to transfer the resist pattern into the hard mask layer 430. According to a further embodiment, a fluorine-based dry-etch process may be used instead of or in combination with the wet-etch process. Using a fluorine-based etch chemistry, for example, a 130 nm thick electron beam resist is typically not completely consumed during the etch of a 10 to 30 nm thick silicon dioxide containing hard mask layer 430.

As shown in FIG. 4B, resist mask residuals 440c may still cover the hard mask structures 430a after formation of the hard mask. According to an embodiment, the resist residuals 440c may be stripped in the following using an ozone-based clean or etch process. The absorber stack 420 protects a top layer of the underlying base section 410 during the ozone clean process so that damaging of the top layer of the base section 410 may be avoided. Alternatively, also a wet-strip process based on H₂SO₄ and H₂O₂ may be used.

Referring to FIG. 4C, the hard mask pattern may be transferred into the anti-reflective layer 424, for example using a fluorine- or chlorine-based dry etch. The hard mask, which is, for example, 30 nm thick, may provide sufficient protection for tantalum-based anti-reflective layers 424 of a typical thickness in the range of 12 nm to 18 nm.

According to a further embodiment, to which FIG. 4D refers, the resist residuals 440d may be removed after patterning the anti-reflective layer 424. FIG. 4D shows the mask 400 with the patterned anti-reflective layer comprising, for example, line- or dot-shaped structures 424a protected by the hard mask structures 430a and separated by trenches 424b, which expose sections of the absorber layer 422 after removing resist residuals 440d.

Referring to FIG. 4E, the pattern is then transferred into the absorber layer 422a, using, for example, an etch chemistry based on fluorine and chlorine. In case of, for example, tantalum containing absorber layers 422, a high etch rate for the absorber layer 422 with high etch selectivity to the anti-reflective layer sections 424 and to the hard mask structures 430a may be achieved. Further, a fluorine/chlorine-based etch chemistry may facilitate an etch stop on materials forming typical top layers of both reflective and transmissive masks, for example, ruthenium, glass, and molybdenum silicide layers.

In the result, the patterning process and the absorber stack/hard mask configuration may be applied to reflective EUV masks as well as for transparent binary and phase shift masks. The hard mask is at least partially consumed during the etch of the absorber stack 420.

FIG. 4E shows only partially consumed hard mask structures 430c, the patterned anti-reflective layer 424a and the patterned absorber layer 422a covering sections of the base section 410. Trenches 422b separate the absorber structures and expose sections of a top layer 418 of the underlying base section 410. Though a typical base section for a reflective EUV mask is illustrated in FIG. 4E, the base section 410 may be replaced by typical base sections of transparent photomasks as well.

With regard to FIG. 4F, the hard mask residuals 430c may be removed using a further HF-based wet-etch process. A HF-based wet-etch process does not substantially deteriorate neither the properties of typical absorber stacks based on tantalum nitride, nor glass substrates as may be used for binary masks, nor molybdenum silicide layers as used for phase-shift masks. In addition, the optical properties of the anti-reflective layer 424a at typical inspection wavelengths, for example, 257 nm, may be retained.

FIG. 4F shows the patterned photomask 400 comprising an absorber pattern including absorber structures 420a separated by trenches 420b exposing sections of an underlying base section 410. As the upper edges of the absorber structures 420a remain covered with hard mask structures 430c up to the end of the absorber patterning process, no corner rounding occurs. The highly anisotropic etch process that is used for patterning the absorber stack 420 provides steep sidewall angles and excellent profile control.

FIG. 5 is a simplified flowchart of a method of manufacturing a mask. A mask blank is provided that includes an anti-reflective layer covering an absorber layer and a hard mask layer disposed over, for example, directly on, the anti-reflective layer in Step 502. The hard mask layer may be patterned to form a hard mask in Step 504, where, for example, first a resist layer may be provided and patterned using electron beam writing. The pattern of the hard mask layer is transferred into the anti-reflective layer in Step 506. Then, in Step 508, the pattern of the hard mask/anti-reflective layer is transferred into the absorber layer. In the following, the hard mask layer may be removed.

We claim:

1. A mask blank, comprising:
an absorber layer being absorbent at an exposure wavelength and being reflective at an inspection wavelength, the inspection wavelength being greater than the exposure wavelength;
an anti-reflective layer disposed over the absorber layer and being less reflective than the absorber layer at the inspection wavelength; and
a hard mask layer disposed over the anti-reflective layer, the hard mask layer having constituents with an atomic number less than or equal to 41.

2. The mask blank according to claim 1, further comprising a resist layer covering the hard mask layer.

3. The mask blank according to claim 1, wherein the hard mask layer is soluble in a HF solution.

4. The mask blank according to claim 1, wherein the constituents of the hard mask layer have an atomic number less than or equal to 24.

5. The mask blank according to claim 4, wherein the hard mask layer contains silicon and oxygen.

6. The mask blank according to claim 5, wherein the hard mask layer is one of a silicon dioxide layer and a silicon oxynitride layer.

7. The mask blank according to claim 1, wherein the hard mask layer comprises carbon.

8. The mask blank according to claim 1, wherein the hard mask layer comprises chromium.

9. The mask blank according to claim 1, wherein the absorber layer comprises a transition metal nitride, the transition metal nitride forming one of a volatile fluorine compound and a volatile chlorine compound.

10. The mask blank according to claim 1, wherein the inspection wavelength is at least 193 nm and does not exceed 800 nm.

11. The mask blank according to claim 1, further comprising a multi-layer reflector disposed below the absorber layer.

12. The mask blank according to claim 1, further comprising a carrier substrate disposed below the absorber layer and transparent at an exposure wavelength that is at least 100 nanometers.

13. The mask blank according to claim 12, further comprising a phase shift layer disposed between the carrier substrate and the absorber layer.

14. A photomask, comprising
a carrier substrate transparent at an exposure wavelength;
an absorber layer opaque at the exposure wavelength and reflective at an inspection wavelength, the inspection wavelength being greater than or equal to the exposure wavelength; and
an anti-reflective layer disposed over the absorber layer and being less reflective than the absorber layer at the inspection wavelength.

15. The photomask according to claim 14, further comprising a hard mask layer disposed over the anti-reflective layer, the constituents of the hard mask layer having an atomic number less than or equal to 41.

16. The photomask according to claim 15, further comprising a resist layer covering the hard mask layer.

17. The photomask according to claim 14, further comprising a phase shift layer disposed between the carrier substrate and the absorber layer.

18. The photomask according to claim 14, wherein:
the anti-reflective layer and the absorber layer are patterned; and
sections of the carrier substrate are exposed.

19. A method for manufacturing a photomask, the method comprising:
providing a mask blank with an absorber layer disposed over an underlayer, an anti-reflective layer disposed over the absorber layer, and a hard mask layer disposed over the anti-reflective layer;
patterning the hard mask layer to form a hard mask;
transferring a pattern of the hard mask into the anti-reflective layer; and
transferring a pattern of the anti-reflective layer into the absorber layer to expose sections of the underlayer.

20. The method according to claim 19, wherein
carrying out the hard mask layer patterning step by transferring a resist mask pattern into the hard mask layer; and
stripping residuals of the resist mask pattern before transferring the pattern of the anti-reflective layer into the absorber layer.

21. The method according to claim 19, which further comprises stripping hard mask residuals through a wet-etch process after transferring the pattern of the anti-reflective layer into the absorber layer.
